(19) United States
(12) Patent Application Publication
(10) Pub. No.: US 2025/0175132 A1
(43) Pub. Date: May 29, 2025

(54) LOW NOISE AMPLIFIER AND METHOD OF OPERATING THE SAME

(71) Applicant: Samsung Electro-Mechanics Co., Ltd., Suwon-si (KR)

(72) Inventors: Taeho LIM, Suwon-si (KR); Gyu-Suck KIM, Suwon-si (KR); Mooyoung RYU, Suwon-si (KR)

(73) Assignee: Samsung Electro-Mechanics Co., Ltd., Suwon-si (KR)

(21) Appl. No.: 18/650,964

(22) Filed: Apr. 30, 2024

(30) Foreign Application Priority Data
Nov. 27, 2023 (KR) 10-2023-0166838

(51) Int. Cl. H03F 3/195

(52) U.S. Cl. CPC H03F 3/195; H03F 2200/294; H03F 2200/451

(57) ABSTRACT

A low noise amplifier is provided. The low noise amplifier includes a first transistor configured to amplify an input radio frequency (RF) signal of a first frequency band, and configured to receive a first bias voltage, a second transistor configured to amplify an input RF signal of a second frequency band, and configured to receive a second bias voltage, a third transistor configured to amplify an output RF signal of the first transistors and configured to receive a third bias voltage, and a fourth transistor configured to amplify an output RF signal of the second transistor, and configured to receive a fourth bias voltage. In a first operation mode, the second bias voltage and the fourth bias voltage may be set to an off-voltage level, and in a second operation mode, the first bias voltage and the third bias voltage may be set to the off-voltage level.

### CROSS-REFERENCE TO RELATED APPLICATIONS

This application claims the benefit under 35 USC § 119 (a) of Korean Patent Application No. 10-2023-0166838 filed on Nov. 27, 2023, in the Korean Intellectual Property Office, the entire disclosure of which is incorporated herein by reference for all purposes.

### BACKGROUND

### 1. Field

The following disclosure relates to a low noise amplifier and a method of operating the same.

### 2. Description of the Background

A low noise amplifier (LNA) may be included in a receiving end of a wireless communication device and is an element that amplifies a weak signal received through an antenna to a signal strong against noise. The low-noise amplifier is an important circuit that determines a noise figure of the receiving end.

Typically, a band selection switch may be located at a front end of a low noise amplifier. The band selection switch switches a plurality of radio frequency (RF) signals, each having a plurality of frequency bands, and transmits the RF frequency signals to the low noise amplifier. In an example, it may be beneficial that the low noise amplifier have a multi-band operation that processes input RF signals having different frequency bands.

However, the band selection switch may cause insertion loss, which may increase the overall noise figure.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a low noise amplifier includes a first transistor configured to amplify an input radio frequency (RF) signal in a first frequency band, and configured to receive a first bias voltage; a second transistor configured to amplify an input RF signal in a second frequency band, and configured to receive a second bias voltage; a third transistor configured to amplify an output RF signal of the first transistor, and configured to receive a third bias voltage; and a fourth transistor configured to amplify an output RF signal of the second transistor, and configured to receive a fourth bias voltage, wherein, in a first operation mode, the second bias voltage and the fourth bias voltage are set to an off-voltage level, and wherein in a second operation mode, the first bias voltage and the third bias voltage are set to an off-voltage level.

In the first operation mode, the first bias voltage and the third bias voltage may be set to an on-voltage level, and in the second operation mode, the second bias voltage and the fourth bias voltage may be set to an on-voltage level.

In the first operation mode, the first transistor and the third transistor may be configured to perform an amplification operation, and the second transistor and the fourth transistor may not perform the amplification operation, and in the second operation mode, the second transistor and the fourth transistor may be configured to perform the amplification operation, and the first transistor and the third transistor may not perform the amplification operation.

The first operation mode may be performed when the input RF signal in the first frequency band is input, and the second operation mode may be performed when the input RF signal in the second frequency band is input.

The input RF signal in the first frequency band and the first bias voltage may be applied to a control terminal of the first transistor, and the input RF signal in the second frequency band and the second bias voltage may be applied to a control terminal of the second transistor.

The third bias voltage may be applied to a control terminal of the third transistor, and the output RF signal of the first transistor may be applied to a first terminal of the third transistor, and the fourth bias voltage may be applied to a control terminal of the fourth transistor, and the output RF signal of the second transistor is applied to a first terminal of the fourth transistor.

The low noise amplifier may further include a first inductor that is connected between a first terminal of the first transistor and a ground, and a second inductor that is connected between a first terminal of the second transistor and the ground.

The low noise amplifier may further include an inductor that includes a first end connected to a power supply voltage, and a second end connected to a second terminal of the third transistor and a second terminal of the fourth transistor.

An inductance value of the inductor may vary depending on the first operation mode and the second operation mode.

Ibn a general aspect, a method of operating a low noise amplifier including a first transistor that amplifies an input radio frequency (RF) signal in a first frequency band and a second transistor that amplifies an input RF signal in a second frequency band includes in a first operation mode in which the input RF signal in the first frequency band is input, setting the second transistor and a fourth transistor to an off-state, wherein a third transistor amplifies an output RF signal of the first transistor; and in a second operation mode in which the input RF signal in the second frequency band is input, setting the first transistor and the third transistor to an off-state, wherein the fourth transistor amplifies an output RF signal of the second transistor.

In the first operation mode, setting the first transistor and the third transistor to an on-state, and in the second operation mode, setting the second transistor and the fourth transistor to an on-state.

In the first operation mode, a bias voltage of the second transistor is set to an off-voltage level, and a bias voltage of the fourth transistor may be set to an off-voltage level, and in the second operation mode, a bias voltage of the first transistor is set to an off-voltage level, and a bias voltage of the third transistor may be set to an off-voltage level.

In the first operation mode, the bias voltage of the first transistor may be set to an on-voltage level, and the bias voltage of the third transistor is set to an on-voltage level, and in the second operation mode, the bias voltage of the second transistor may be set to an on-voltage level, and the bias voltage of the fourth transistor is set to an on-voltage level.

In the first operation mode, an RF signal path may be formed through the first transistor and the third transistor, and in the second operation mode, an RF signal path may be formed through the second transistor and the fourth transistor.

In a general aspect, a low noise amplifier includes a first transistor configured to amplify an input radio frequency (RF) signal in a first frequency band; a second transistor configured to amplify an input RF signal in a second frequency band; a third transistor configured to amplify an output RF signal of the first transistor, and configured to turn off when the first transistor turns off; and a fourth transistor configured to amplify an output RF signal of the second transistor, and configured to turn off when the second transistor turns off.

In a first operation mode, an RF signal path may be formed through the first transistor and the third transistor, and in a second operation mode, an RF signal path may be formed through the second transistor and the fourth transistor.

Other features and aspects will be apparent from the following detailed description, the drawings, and the claims.

### BRIEF DESCRIPTION OF DRAWINGS

FIG. 1 illustrates a general band selection switch and an example low noise amplifier (LNA), in accordance with one or more embodiments.

FIG. 2 illustrates a low noise amplifier, in accordance with one or more embodiments.

FIG. 3A illustrates an operation and radio frequency (RF) signal path of the example low noise amplifier in a first operation mode.

FIG. 3B illustrates an operation and RF signal path of the example low noise amplifier in a second operation mode.

FIG. 4 illustrates an example low noise amplifier, in accordance with one or more embodiments.

FIG. 5A illustrates an operation and RF signal path of the low noise amplifier in the first operation mode.

FIG. 5B illustrates the operation and RF signal path of the low noise amplifier in the first operation mode.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the one or more examples, an RF signal may have a format according to other random wireless and wired protocols designated by, as only examples, Wi-Fi (IEEE 802.11 family, etc.), WiMAX (IEEE 802. 16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

In addition, unless explicitly described to the contrary, the word “comprise”, and variations such as “comprises” or “comprising”, will be understood to imply the inclusion of stated elements but not the exclusion of any other elements.

One or more examples may provide a low noise amplifier that reduces a noise figure and has a multi-band operation.

In accordance with one or more examples, by separately forming the RF signal path according to each frequency band, it is possible to improve the isolation.

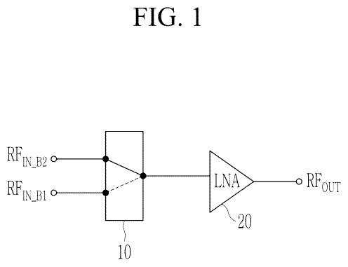

FIG. 1 illustrates a general band selection switch 10 and a low noise amplifier (LNA) 20.

An input RF signal RF_{IN_B1} in a first frequency band and an input RF signal RF_{IN_B2} in a second frequency band may be input to the band selection switch 10. The input RF signal in the first frequency band is an RF signal having a first frequency band, and the input RF signal in the second frequency band is an RF signal having a second frequency band. In an example, the first frequency band may be a different frequency band from the second frequency band.

The band selection switch 10 may select and output one of the input RF signal RF_{IN_B1} in the first frequency band and the input RF signal RF_{IN_B2} in the second frequency band. That is, the band selection switch 10 may switch the input RF signal in the first frequency band and the input RF signal RF_{IN_B2} in the second frequency band by the control signal. In an example, the band selection switch 10 may be a single pole N throw (SPNT) switch or, as an example, a single pole double throw (SPDT) switch.

The low noise amplifier 20 may amplify the RF signal output from the band selection switch 10. When the input RF signal RF_{IN_B1} in the first frequency band is input from the band selection switch 10, the low noise amplifier 20 amplifies the input RF signal RF_{IN_B1} in the first frequency band. When the input RF signal RF_{IN_B2} in the second frequency band is input from the band selection switch 10, the low noise amplifier 20 amplifies an input RF signal RF_{IN_B2} in the second frequency band. That is, the low noise amplifier 20 may have a multi-band operation that amplifies input RF signals having different frequency bands.

In the structure illustrated in FIG. 1, insertion loss IL may occur due to the band selection switch 10. This insertion loss may affect the overall noise figure. In the structure illustrated in FIG. 1, the overall noise figure may be expressed as Equation 1 below.

$$NF\_total = IL\_BSS + NF\_LNA \qquad Equation 1$$

In Equation 1, NF_total represents the overall noise figure, IL_BSS represents the insertion loss IL of the band selection switch 10, and NF_LNA represents the noise figure of the low noise amplifier 20.

To reduce the insertion loss due to the band select switch 10, it may be necessary to remove the band select switch 10. In this example, it may be advantageous for the low noise amplifier 20 to internally perform the operation of the band selection switch 10, and this low noise amplifier will be described below. That is, a low noise amplifier 200A or 200B described below may simultaneously perform, not only an amplification operation, but also an operation of the band selection switch.

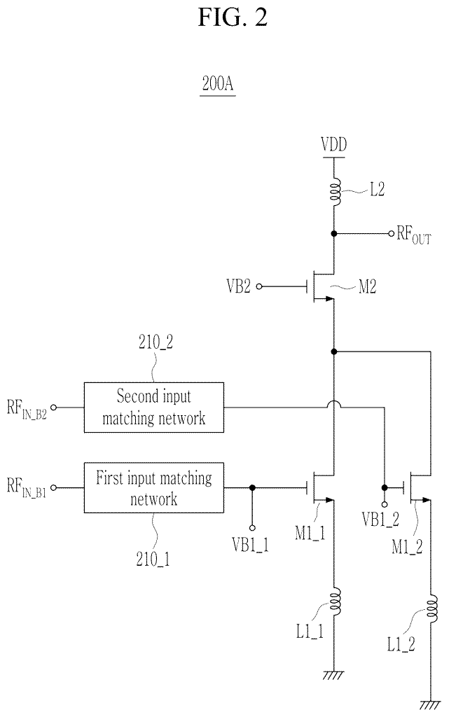

FIG. 2 is a circuit diagram illustrating the low noise amplifier 200A, in accordance with one or more embodiments.

As illustrated in FIG. 2, the low noise amplifier 200A, in accordance with one or more embodiments, may include a first input matching network 210_1, a second input matching network 210_2, a first transistor M1_1, a second transistor M1_2, and a third transistor M2. The low noise amplifier 200A may further include an inductor first L1_1, a second inductor L1_2, and a third inductor L2.

In FIG. 2, the transistors M1_1, M1_2, and M2 may be implemented as various transistors such as, but not limited to, a field effect transistor (FET) and a bipolar transistor. In FIG. 2, the transistors M1_1, M1_2, and M2 are illustrated as n-type. However, this is only an example, and the transistors M1_1, M1_2, and M2 may be replaced with p-type transistors. Hereinafter, for convenience of description, it is assumed that the transistors M1_1, M1_2, and M2 are FETs, but may be replaced with other transistors.

In an example, gates of the transistors M1_1, M1_2, and M2 may operate as control terminals, and therefore, may be respectively identified as a ‘control terminal’. Drains of the transistors M1_1, M1_2, and M2 are one terminal of the transistor, and therefore, may be respectively identified as a ‘first terminal or second terminal’. Sources of the transistors M1_1, M1_2, and M2 are one terminal of the transistor, and therefore, may be identified as the a “second terminal” or a “first terminal”.

The input RF signal RF_{IN_B1} in the first frequency band may be input to the first input matching network 210_1, and the first input matching network 210_1 may be connected between a terminal to which the input RF signal RF_{IN_B1} in the first frequency band is input and the gate of the transistor M1_1. The first input matching network 210_1 may perform impedance matching between the input RF signal RF_{IN_B1} in the first frequency band and the transistor M1_1. The input matching network 210_1 may be implemented as a combination of at least one of an inductor and a capacitor.

The input RF signal RF_{IN_B2} in the second frequency band may be input to the second input matching network 210_2, and the second input matching network 210_2 may be connected between a terminal to which the input RF signal RF_{IN_B2} in the second frequency band is input and the gate of the transistor M1_2. The second input matching network 210_2 may perform impedance matching between the input RF signal RF_{IN_B2} in the second frequency band and the transistor M1_2. The input matching network 210_2 may be implemented as a combination of at least one of an inductor and a capacitor.

The transistor M1_1 may be an amplification transistor, and the input RF signal RF_{IN_B1} in the first frequency band may be input to the gate of the transistor M1_1. The transistor M1_1 amplifies the input RF signal RF_{IN_B1} in the first frequency band. A bias voltage VB1_1 may be applied to the gate of the transistor M1_1. The transistor M1_1 may perform an amplification operation based on the bias voltage VB1_1. The amplified signal may be output to the drain of the transistor M1_1. Since the input RF signal RF_{IN_B1} in the first frequency band to be amplified is input to the gate of the transistor M1_1 and the amplified signal is output to the drain of the transistor M1_1, the transistor M1_1 may be a common-source amplification structure.

In an example, the bias voltage VB1_1 may have two voltage levels. That is, the bias voltage VB1_1 may have an on-voltage level VB1_1_ON and an off-voltage level VB1_1_OFF. When the bias voltage VB1_1 is at the on-voltage level VB1_1_ON, the transistor M1_1 may perform the amplification operation. When the bias voltage VB1_1 is at the off-voltage level VB1_1_OFF, the transistor M1_1 may not perform the amplification operation. When the low noise amplifier 200A amplifies the input RF signal RF_{IN_B1} in the first frequency, the bias voltage VB1_1 may be set to the on-voltage level VB1_1_ON. When the low noise amplifier 200A amplifies the input RF signal RF_{IN_B2} in the second frequency, the bias voltage VB1_1 may be set to the off-voltage level VB1_1_OFF. As one example, the on-voltage level VB1_1_ON may be 1.8V, and the off-voltage level VB1_1_OFF may be 0V.

The transistor M1_2 may be an amplification transistor, and the input RF signal RF_{IN_B2} in the second frequency band may be input to the gate of the transistor M1_2. The transistor M1_2 amplifies the input RF signal RF_{IN_B2} in the second frequency band. A bias voltage VB1_2 may be applied to the gate of the transistor M1_2. The transistor M1_2 may perform the amplification operation based on the bias voltage VB1_2. The amplified signal may be output to the drain of the transistor M1_2. Since the input RF signal RF_{IN_B2} in the second frequency band to be amplified is input to the gate of the transistor M1_2 and the amplified signal is output to the drain of the transistor M1_2, the transistor M1_2 may be the common-source amplification structure.

In an example, the bias voltage VB1_2 may have two voltage levels. That is, the bias voltage VB1_2 may have an on-voltage level VB1_2_ON and an off-voltage level VB1_2_OFF. When the bias voltage VB1_2 is at the on-voltage level VB1_2_ON, the transistor M1_2 may perform the amplification operation. When the bias voltage VB1_2 is at the off-voltage level VB1_2_OFF, the transistor M1_2 may not perform the amplification operation. When the low noise amplifier 200A amplifies the input RF signal RF_{IN_B2} in the second frequency, the bias voltage VB1_2 may be set to the on-voltage level VB1_2_ON. When the low noise amplifier 200A amplifies the input RF signal RF_{IN_B1} in the first frequency, the bias voltage VB1_2 may be set to the off-voltage level VB1_2_OFF. As one example, the on-voltage level VB1_2_ON may be 1.8V, and the off-voltage level VB1_2_OFF may be 0V.

The inductor L1_1 may be connected between the source of the transistor M1_1 and a ground. The inductor L1_1 may be a degeneration circuit and may improve impedance matching of the input matching network 210_1. Through this, the inductor L1_1 may optimize a gain and noise figure of the transistor M1_1. When the transistor M1_1 is implemented as the bipolar transistor, the inductor L1_1 may provide emitter degeneration. When the transistor M1_1 is implemented as a field effect transistor (FET), the inductor L1_1 may provide source degeneration. In an example, the inductor L1_1 may be replaced with a resistor to operate as the degeneration circuit.

The inductor L1_2 may be connected between the source of the transistor M1_2 and the ground. The inductor L1_2 is the degeneration circuit and may improve impedance matching of the input matching network 210_2. Accordingly, the inductor L1_2 may optimize a gain and noise figure of the transistor M1_2. When the transistor M1_2 is implemented as the bipolar transistor, the inductor L1_2 may provide the emitter degeneration. When the transistor M1_2 is implemented as the field effect transistor (FET), the inductor L1_2 may provide the source degeneration. In an example, the inductor L1_2 may be replaced with the resistor to operate as the degeneration circuit.

The transistor M2 may form a cascode structure together with the transistor M1_1 and may amplify the output signal of the transistor M1_1. The transistor M2 may form a cascode structure together with the transistor M1_2 and may amplify the output signal of the transistor M1_2. That is, the transistor M2 may amplify both the output signal of transistor M1_1 and the output signal of transistor M1_2.

The source of the transistor M2 may be connected to the drain of transistor M1_1 and the drain of transistor M1_2. The source of the transistor M2 may receive the RF signal to be amplified from the transistor M1_1, and the source of the transistor M2 may receive the RF signal to be amplified from the transistor M1_2. That is, the transistor M2 may amplify the RF signal output from the drain of the transistor M1_1, and the transistor M2 may amplify the RF signal output from the drain of the transistor M1_2. The drain of the transistor M2 may output the amplified signal. That is, the drain of the transistor M2 is the output terminal of the low noise amplifier 200A and outputs an output RF signal RF_{OUT}.

A bias voltage VB2 may be applied to the gate of the transistor M2. The transistor M1_2 may perform the amplification operation based on the bias voltage VB2. Since the transistor M2 amplifies both the output signal of the transistor M1_1 and the output signal of the transistor M1_2, the bias voltage VB2 may always be set to the on-voltage level VB2_ON.

The inductor L2 may be connected between a power supply voltage VDD and the drain of the transistor M2. The transistor M2 may receive the power supply voltage VDD through the inductor L2. In an example, the inductor L2 may perform an RF choke operation or an output impedance matching operation.

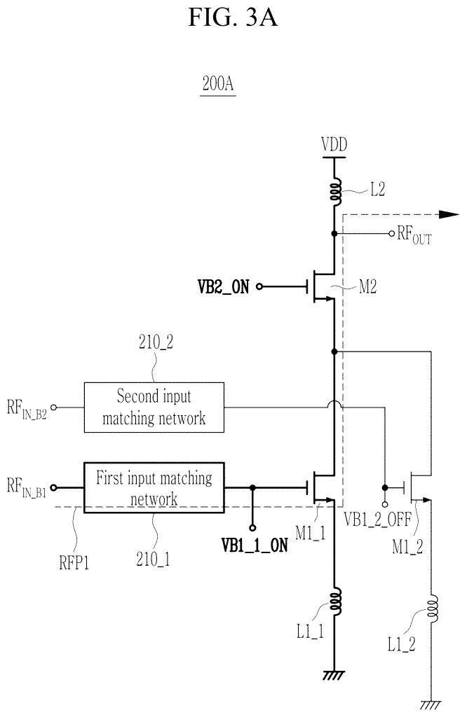

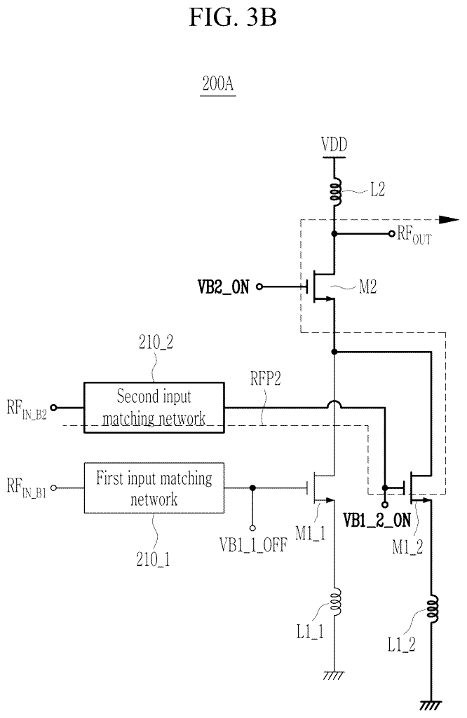

Hereinafter, the operation and RF signal path of the low noise amplifier 200A in the first and second operation modes will be described with reference to FIGS. 3A and 3B. In an example, the first operation mode may be a mode when the input RF signal RF_{IN_B1} in the first frequency band is input to the low noise amplifier 200A. The second operation mode may be a mode when the input RF signal RF_{IN_B2} in the second frequency band is input to the low noise amplifier 200A.

FIG. 3A is a diagram illustrating the operation and RF signal path of the low noise amplifier 200A in the first operation mode.

In the first operation mode, the input RF signal RF_{IN_B1} in the first frequency band is input. In this example, the bias voltage VB1_1 is set to the on-voltage level VB1_1_ON, and the bias voltage VB1_2 is set to the off-voltage level VB1_2_OFF. The bias voltage VB2 is set to the on-voltage level VB2_ON. Accordingly, the transistor M1_1 and the transistor M2 perform the amplification operation, and the transistor M1_2 does not perform the amplification operation.

In the first operation mode, an RF signal path RFP1 is formed through the first input matching network 210_1, the transistor M1_1, and the transistor M2.

FIG. 3B is a diagram illustrating an operation and RF signal path of the low noise amplifier 200A in the second operation mode.

In the second operation mode, the input RF signal RF_{IN_B2} in the second frequency band is input. In this example, the bias voltage VB1_1 is set to the off-voltage level VB1_1_OFF, and the bias voltage VB1_2 is set to the on-voltage level VB1_2_ON. The bias voltage VB2 is set to the on-voltage level VB2_ON. Accordingly, the transistor M1_2 and the transistor M2 perform the amplification operation, and the transistor M1_1 does not perform the amplification operation.

In the second operation mode, an RF signal path RFP2 is formed through the second input matching network 210_2, the transistor M1_2, and the transistor M2.

In this way, the low noise amplifier 200A, in accordance with one or more embodiments, may selectively amplify the input RF signal in each frequency band by adjusting the level of the bias voltage. Accordingly, a separate band selection switch may not be needed at the front end of the low noise amplifier 200A. Since the insertion loss caused by the band selection switch may not occur, the overall noise figure may be reduced. That is, the low noise amplifier 200A, in accordance with one or more embodiments, may internally perform the operation of the band selection switch, thereby not only reducing the noise figure, but also performing the multi-band operation.

In an example, referring to FIGS. 3A and 3B, in the first operation mode and the second operation mode, the transistor M2 performs the amplification operation. In this example, the RF signal path RFP1 and the RF signal path RFP2 may be formed in common in the transistor M2. As a result, the isolation may deteriorate due to the input RF signal input to the transistor (for example, the transistor M1_2 in the first operation mode and the transistor M1_1 in the second operation mode) that does not perform the amplification operation. That is, since there is some overlap between the RF signal path RFP1 and the RF signal path RFP2, the isolation between the two RF signal paths may deteriorate. Hereinafter, an embodiment that may improve the deterioration in the isolation will be described.

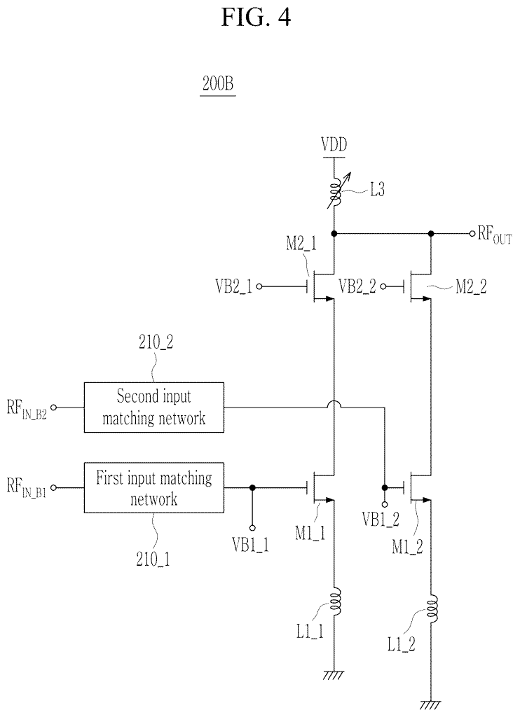

FIG. 4 is a diagram illustrating a low noise amplifier 200B, in accordance with one or more embodiments.

As illustrated in FIG. 4, the low noise amplifier 200B, in accordance with one or more embodiments, may include a first input matching network 210_1, a second input matching network 210_2, a first transistor M1_1, a second transistor M1_2, a third transistor M2_1, and a fourth transistor M2_2. The low noise amplifier 200B may further include a first inductor L1_1, a second inductor L1_2, and a third inductor L3. The low noise amplifier 200B of FIG. 4 is similar to the low noise amplifier 200A of FIG. 2, and therefore, overlapping descriptions thereof may be omitted.

Referring to FIG. 4, the transistors M1_1, M1_2, M2_1, and M2_2 may be implemented as various transistors such as, but not limited to, a field effect transistor (FET) and a bipolar transistor. In FIG. 4, the transistors M1_1, M1_2, M2_1, and M2_2 are illustrated as n-type transistors. However, this is only an example, and the transistors M1_1, M1_2, M2_1, and M2_2 may be replaced with p-type transistors. Hereinafter, for convenience of description, it is assumed that the transistors M1_1, M1_2, M2_1, and M2_2 are FETs, but may be replaced with other transistors.

In an example, gates of the transistors M1_1, M1_2, M2_1, and M2_2 may operate as control terminals, and therefore, may be respectively identified as a ‘control terminal’. Drains of the transistors M1_1, M1_2, M2_1, and M2_2 are one terminal of the transistor, and therefore, may be respectively identified as a ‘first terminal or second terminal’. Sources of the transistors M1_1, M1_2, M2_1, and M2_2 are one terminal of the transistor, and therefore, may be respectively identified as a “second terminal” or a “first terminal”.

An input RF signal RF_{IN_B1} in a first frequency band may be input to the first input matching network 210_1, and the first input matching network 210_1 may perform impedance matching between the input RF signal RF_{IN_B1} in the first frequency band and the transistor M1_1.

An input RF signal RF_{IN_B2} in a second frequency band may be input to the second input matching network 210_2, and the second input matching network 210_2 may perform impedance matching between the input RF signal RF_{IN_B2} in the second frequency band and the transistor M1_2.

The input RF signal RF_{IN_B1} in the first frequency band is input to the gate of the transistor M1_1, and the transistor M1_1 amplifies the input RF signal RF_{IN_B1} in the first frequency band. A bias voltage VB1_1 is applied to the gate of the transistor M1_1, and the transistor M1_1 may perform an amplification operation due to the bias voltage VB1_1. The amplified signal may be output to the drain of the transistor M1_1.

The bias voltage VB1_1 may have an on-voltage level VB1_1_ON and an off-voltage level VB1_1_OFF. When the bias voltage VB1_1 is at the on-voltage level VB1_1_ON, the transistor M1_1 may perform the amplification operation. When the bias voltage VB1_1 is at the off-voltage level VB1_1_OFF, the transistor M1_1 may not perform the amplification operation. When the low noise amplifier 200B amplifies the input RF signal RF_{IN_B1} in the first frequency, the bias voltage VB1_1 may be set to the on-voltage level VB1_1_ON. When the low noise amplifier 200B amplifies the input RF signal RF_{IN_B2} in the second frequency, the bias voltage VB1_1 may be set to the off-voltage level VB1_1_OFF.

The input RF signal RF_{IN_B2} in the second frequency band is input to the gate of the transistor M1_2, and the transistor M2_1 amplifies the input RF signal RF_{IN_B2} in the second frequency band. A bias voltage VB1_2 is applied to the gate of the transistor M1_2, and the transistor M1_2 may perform the amplification operation based on the bias voltage VB1_2. The amplified signal may be output to the drain of the transistor M1_2.

The bias voltage VB1_2 may have an on-voltage level VB1_2_ON and an off-voltage level VB1_2_OFF. When the bias voltage VB1_2 is at the on-voltage level VB1_2_ON, the transistor M1_2 may perform the amplification operation. When the bias voltage VB1_2 is at the off-voltage level VB1_2_OFF, the transistor M1_2 may not perform the amplification operation. When the low noise amplifier 200B amplifies the input RF signal RF_{IN_B2} in the second frequency, the bias voltage VB1_2 may be set to the on-voltage level VB1_2_ON. When the low noise amplifier 200B amplifies the input RF signal RF_{IN_B1} in the first frequency, the bias voltage VB1_2 may be set to the off-voltage level VB1_2_OFF.

The inductor L1_1 may be connected between the source of the transistor M1_1 and a ground, and the inductor L1_2 may be connected between the source of the transistor M1_2 and the ground. Since the inductors L1_1 and L1_2, which are the degeneration inductors, are each connected to the transistor M1_1 and transistor M1_2, respectively, the low noise amplifier 200B may optimize the gain and noise figure according to the frequency band. That is, the inductor L1_1 may be implemented to be optimized for the input RF signal RF_{IN_B1} in the first frequency band, and the inductor L1_2 may be implemented to be optimized for the input RF signal RF_{IN_B2} in the second frequency band.

The transistor M2_1 may form a cascode structure together with the transistor M1_1, and may amplify the output signal of the transistor M1_1. The source of the transistor M2_1 is connected to the drain of the transistor M1_1, and the source of the transistor M2_1 may receive an RF signal to be amplified from the transistor M1_1. That is, the transistor M2_1 may amplify the RF signal output from the drain of the transistor M1_1. Additionally, the drain of transistor M2_1 is connected to the drain of transistor M2_2, and the drain of transistor M2_1 may output the amplified signal. That is, the drain of the transistor M2_1 is the output terminal of the low noise amplifier 200B, and outputs an output RF signal RF_{OUT}.

A bias voltage VB2_1 may be applied to the gate of the transistor M2_1. The transistor M2_1 may perform the amplification operation based on the bias voltage VB2_1. In an example, the bias voltage VB2_1 may have two voltage levels. That is, the bias voltage VB2_1 may have an on-voltage level VB2_1_ON and an off-voltage level VB2_1_OFF. When the bias voltage VB2_1 is at the on-voltage level VB2_1_ON, the transistor M1_2 may perform the amplification operation. When the bias voltage VB2_1 is at the off-voltage level VB2_1_OFF, the transistor M2_1 may not perform the amplification operation. When the low noise amplifier 200B amplifies the input RF signal RF_{IN_B1} in the first frequency, the bias voltage VB2_1 may be set to the on-voltage level VB2_1_ON. When the low noise amplifier 200B amplifies the input RF signal RF_{IN_B2} in the second frequency, the bias voltage VB2_1 may be set to the off-voltage level VB2_1_OFF. In an example, the on-voltage level VB2_1_ON may be 1.8V, and the off-voltage level VB2_1_OFF may be 0V.

The transistor M2_2 may form a cascode structure together with the transistor M1_2, and may amplify the output signal of the transistor M1_2. The source of the transistor M2_2 is connected to the drain of the transistor M1_2, and the source of the transistor M2_2 may receive an RF signal to be amplified from the transistor M1_2. That is, the transistor M2_2 may amplify the RF signal output from the drain of the transistor M1_2. Additionally, the drain of transistor M2_2 is connected to the drain of transistor M2_1, and the drain of transistor M2_2 may output the amplified signal. That is, the drain of the transistor M2_2 is the output terminal of the low noise amplifier 200B and outputs the output RF signal RF_{OUT}.

A bias voltage VB2_2 may be applied to the gate of the transistor M2_2. The transistor M2_2 may perform the amplification operation based on the bias voltage VB2_2.

In an example, the bias voltage VB2_2 may have two voltage levels. That is, the bias voltage VB2_2 may have an on-voltage level VB2_2_ON and an off-voltage level VB2_2_OFF. When the bias voltage VB2_2 is at the on-voltage level VB2_2_ON, the transistor M2_2 may perform the amplification operation. When the bias voltage VB2_2 is at the off-voltage level VB2_2_OFF, the transistor M2_2 may not perform the amplification operation. When the low noise amplifier 200B amplifies the input RF signal RF_{IN_B2} in the second frequency, the bias voltage VB2_2 may be set to the on-voltage level VB2_2_ON. When the low noise amplifier 200B amplifies the input RF signal RF_{IN_B1} in the first frequency, the bias voltage VB2_2 may be set to the off-voltage level VB2_2_OFF. In an example, the on-voltage level VB2_2_ON may be 1.8V, and the off-voltage level VB2_2_OFF may be 0V.

A first end of the inductor L3 may be connected to the power supply voltage VDD, and a second end of the inductor L3 may be connected to the drain of the transistor M2_1 and the drain of the transistor M2_2. The transistor M2_1 and the transistor M2_2 may receive the power supply voltage VDD through the inductor L3. In an example, the inductor L3 may perform an RF choke operation or an output impedance matching operation.

In an example, the inductor L3 may be a variable inductor. When the inductor L3 is the variable inductor, an inductance value of the inductor L3 may vary depending on the frequency band of the input RF signal. When the input RF signal RF_{IN_B1} in the first frequency band is input, the inductance value of the inductor L3 may be set to be optimized for the input RF signal RF_{IN_B1} in the first frequency band. When the input RF signal RF_{IN_B2} in the second frequency band is input, the inductance value of the inductor L3 may be set to be optimized for the input RF signal RF_{IN_B2} in the second frequency band. That is, the inductance value of the inductor L3 may vary depending on the operation mode (first and second operation modes).

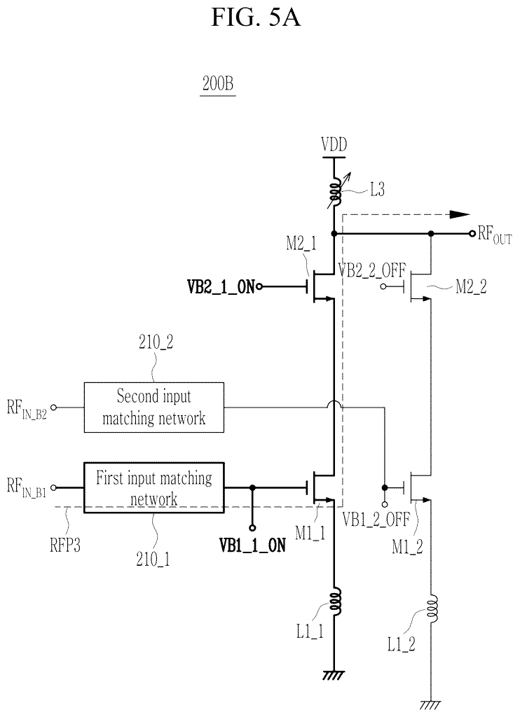

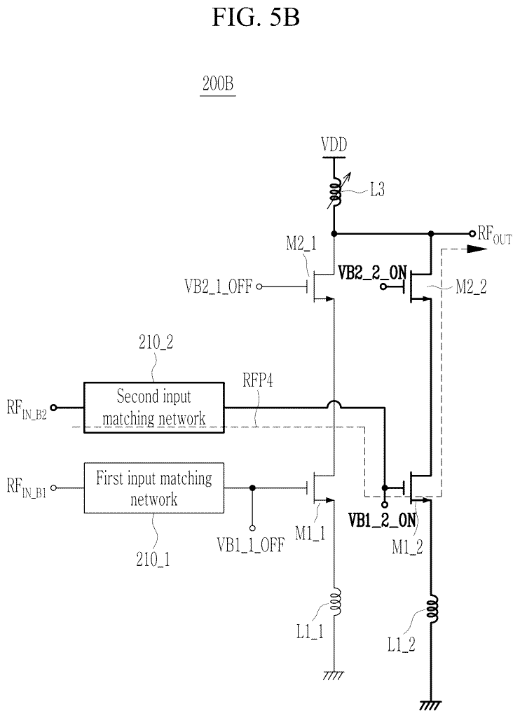

Hereinafter, the operation and RF signal path of the low noise amplifier 200B in the first and second operation modes will be described with reference to FIGS. 5A and 5B. In an example, the first operation mode may be when the input RF signal RF_{IN_B1} in the first frequency band is input to the low noise amplifier 200B. The second operation mode may be when the input RF signal RF_{IN_B2} in the second frequency band is input to the low noise amplifier 200B.

FIG. 5A illustrates the operation and RF signal path of the low noise amplifier 200B in the first operation mode.

Referring to FIG. 5A, in the first operation mode, the input RF signal RF_{IN_B1} in the first frequency band is input. In this example, the bias voltage VB1_1 is set to the on-voltage level VB1_1_ON, and the bias voltage VB2_1 is set to the on-voltage level VB2_1_ON. The bias voltage VB1_2 is set to the off-voltage level VB1_2_OFF, and the bias voltage VB2_2 is set to the off-voltage level VB2_2_OFF. Accordingly, the transistor M1_1 and the transistor M2_1 perform the amplification operation, and the transistor M1_2 and the transistor M2_2 do not perform the amplification operation.

In the first operation mode, an RF signal path RFP3 is formed through the first input matching network 210_1, the transistor M1_1, and the transistor M2_1.

FIG. 5B illustrates the operation and RF signal path of the low noise amplifier 200B in the first operation mode.

Referring to FIG. 5B, in the second operation mode, the input RF signal RF_{IN_B2} in the second frequency band is input. In this example, the bias voltage VB1_2 is set to the on-voltage level VB1_2_ON, and the bias voltage VB2_2 is set to the on-voltage level VB2_1_ON. The bias voltage VB1_1 is set to the off-voltage level VB1_1_OFF, and the bias voltage VB2_1 is set to the off-voltage level VB2_1_OFF. Accordingly, the transistor M1_2 and the transistor M2_2 perform the amplification operation, and the transistor M1_1 and the transistor M2_1 do not perform the amplification operation.

In the second operation mode, an RF signal path RFP4 is formed through the second input matching network 210_1, the transistor M1_2, and the transistor M2_2.

In this manner, the low noise amplifier 200B, in accordance with one or more embodiments, may selectively amplify the input RF signal in each frequency band by adjusting the level of the bias voltage. Accordingly, a separate band selection switch may not be needed at the front end of the low noise amplifier 200B. Since the insertion loss caused by the band selection switch may not occur, the overall noise figure may be reduced. That is, the low noise amplifier 200B, in accordance with one or more embodiments, internally performs the operation of the band selection switch, thereby not only reducing the noise figure but also performing the multi-band operation.

Referring to FIGS. 5A and 5B, in the low noise amplifier 200B, in accordance with one or more embodiments, the RF signal path RFP3 in the first operation mode and the RF signal path RFP4 in the second operation mode are formed as different paths. Accordingly, the isolation between the two RF signal paths may be improved. That is, the RF signal path RFP3 in the first operation mode and the RF signal path RFP4 in the second operation mode may not affect each other, and thus, the isolation may be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A low noise amplifier, comprising:
a first transistor configured to amplify an input radio frequency (RF) signal in a first frequency band, and configured to receive a first bias voltage;
a second transistor configured to amplify an input RF signal in a second frequency band, and configured to receive a second bias voltage;
a third transistor configured to amplify an output RF signal of the first transistor, and configured to receive a third bias voltage; and
a fourth transistor configured to amplify an output RF signal of the second transistor, and configured to receive a fourth bias voltage,
wherein, in a first operation mode, the second bias voltage and the fourth bias voltage are set to an off-voltage level, and
wherein in a second operation mode, the first bias voltage and the third bias voltage are set to an off-voltage level.

2. The low noise amplifier of claim 1, wherein:
in the first operation mode, the first bias voltage and the third bias voltage are set to an on-voltage level, and
in the second operation mode, the second bias voltage and the fourth bias voltage are set to an on-voltage level.

3. The low noise amplifier of claim 2, wherein:
in the first operation mode, the first transistor and the third transistor are configured to perform an amplification operation, and the second transistor and the fourth transistor do not perform the amplification operation, and
in the second operation mode, the second transistor and the fourth transistor are configured to perform the amplification operation, and the first transistor and the third transistor do not perform the amplification operation.

4. The low noise amplifier of claim 1, wherein:
the first operation mode is performed when the input RF signal in the first frequency band is input, and
the second operation mode is performed when the input RF signal in the second frequency band is input.

5. The low noise amplifier of claim 1, wherein:
the input RF signal in the first frequency band and the first bias voltage are applied to a control terminal of the first transistor, and
the input RF signal in the second frequency band and the second bias voltage are applied to a control terminal of the second transistor.

6. The low noise amplifier of claim 5, wherein:
the third bias voltage is applied to a control terminal of the third transistor, and the output RF signal of the first transistor is applied to a first terminal of the third transistor, and
the fourth bias voltage is applied to a control terminal of the fourth transistor, and the output RF signal of the second transistor is applied to a first terminal of the fourth transistor.

7. The low noise amplifier of claim 6, further comprising:
a first inductor that is connected between a first terminal of the first transistor and a ground, and
a second inductor that is connected between a first terminal of the second transistor and the ground.

8. The low noise amplifier of claim 6, further comprising:
an inductor that comprises a first end connected to a power supply voltage, and a second end connected to a second terminal of the third transistor and a second terminal of the fourth transistor.

9. The low noise amplifier of claim 8, wherein an inductance value of the inductor varies depending on the first operation mode and the second operation mode.

10. A method of operating a low noise amplifier comprising a first transistor that amplifies an input radio frequency (RF) signal in a first frequency band and a second transistor that amplifies an input RF signal in a second frequency band, the method comprising:
in a first operation mode in which the input RF signal in the first frequency band is input, setting the second transistor and a fourth transistor to an off-state, wherein a third transistor amplifies an output RF signal of the first transistor; and
in a second operation mode in which the input RF signal in the second frequency band is input, setting the first transistor and the third transistor to an off-state, wherein the fourth transistor amplifies an output RF signal of the second transistor.

11. The method of claim 10, further comprising:
in the first operation mode, setting the first transistor and the third transistor to an on-state, and
in the second operation mode, setting the second transistor and the fourth transistor to an on-state.

12. The method of claim 11, wherein:
in the first operation mode, a bias voltage of the second transistor is set to an off-voltage level, and a bias voltage of the fourth transistor is set to an off-voltage level, and
in the second operation mode, a bias voltage of the first transistor is set to an off-voltage level, and a bias voltage of the third transistor is set to an off-voltage level.

13. The method of claim 12, wherein:
in the first operation mode, the bias voltage of the first transistor is set to an on-voltage level, and the bias voltage of the third transistor is set to an on-voltage level, and
in the second operation mode, the bias voltage of the second transistor is set to an on-voltage level, and the bias voltage of the fourth transistor is set to an on-voltage level.

14. The method of claim 13, wherein:
in the first operation mode, an RF signal path is formed through the first transistor and the third transistor, and
in the second operation mode, an RF signal path is formed through the second transistor and the fourth transistor.

15. A low noise amplifier comprising:
a first transistor configured to amplify an input radio frequency (RF) signal in a first frequency band;
a second transistor configured to amplify an input RF signal in a second frequency band;
a third transistor configured to amplify an output RF signal of the first transistor, and configured to turn off when the first transistor turns off; and
a fourth transistor configured to amplify an output RF signal of the second transistor, and configured to turn off when the second transistor turns off.

16. The method of claim 15, wherein:
in a first operation mode, an RF signal path is formed through the first transistor and the third transistor, and
in a second operation mode, an RF signal path is formed through the second transistor and the fourth transistor.
